(19) United States
(12) Patent Application Publication
(10) Pub. No.: US 2025/0275342 A1
(43) Pub. Date: Aug. 28, 2025

(54) LIGHT-EMITTING DEVICE AND METHOD FOR MANUFACTURING LIGHT-EMITTING DEVICE

(71) Applicant: NICHIA CORPORATION, Anan-shi (JP)

(72) Inventor: Kenji OZEKI, Tokushima-shi (JP)

(21) Appl. No.: 19/036,940

(22) Filed: Jan. 24, 2025

(30) Foreign Application Priority Data
Feb. 22, 2024 (JP) 2024-025815
Oct. 17, 2024 (JP) 2024-182094

(51) Int. Cl. H10H 29/853; H10H 29/01

(52) U.S. Cl. CPC H10H 29/853; H10H 29/0362

(57) ABSTRACT

A method for manufacturing a light-emitting device includes providing a structure body. The structure body includes a wiring substrate, a light-emitting element, and a protection element. The wiring substrate includes a wiring part at an upper surface of the wiring substrate. The light-emitting element includes a pair of first electrodes, a first semiconductor layer, and a first element substrate. The protection element includes a pair of second electrodes, a second semiconductor layer, and a second element substrate. The pair of first electrodes and the pair of second electrodes face the upper surface of the wiring substrate. The pair of first electrodes and the pair of second electrodes are connected to the wiring part. The method includes removing at least a portion of the first element substrate of the light-emitting element and at least a portion of the second element substrate of the protection element from the structure body.

### CROSS-REFERENCE TO RELATED APPLICATIONS

This application is based upon and claims the benefit of priority from the prior Japanese Patent Application No. 2024-025815, filed on Feb. 22, 2024, and the prior Japanese Patent Application No. 2024-182094, filed on Oct. 17, 2024; the entire contents of which are incorporated herein by reference.

### FIELD

Embodiments described herein relate generally to a light-emitting device and a method for manufacturing a light-emitting device.

### BACKGROUND

In recent years, light-emitting devices that use light-emitting diodes (LEDs) are becoming increasingly popular. It is desirable to increase the light extraction efficiency of such a light-emitting device to realize both higher brightness and power conservation.

### SUMMARY

Embodiments are directed to a light-emitting device in which the light extraction efficiency can be increased and a method for manufacturing such a light-emitting device.

According to one aspect of the present disclosure, a method for manufacturing a light-emitting device includes: providing a structure body, the structure body including a wiring substrate including a wiring part at an upper surface, a light-emitting element in which a pair of first electrodes, a first semiconductor layer, and a first element substrate are stacked, and a protection element in which a pair of second electrodes, a second semiconductor layer, and a second element substrate are stacked, wherein the pair of first electrodes and the pair of second electrodes face the upper surface of the wiring substrate, and the pair of first electrodes and the pair of second electrodes are connected to the wiring part; and removing at least a portion of the first element substrate of the light-emitting element and at least a portion of the second element substrate of the protection element from the structure body.

According to one aspect of the present disclosure, a light-emitting device includes a wiring substrate, a light-emitting element arranged on the wiring substrate, a protection element arranged on the wiring substrate, a light-transmitting member arranged on the light-emitting element, and a covering member arranged on the wiring substrate, the covering member not covering an upper surface of the light-transmitting member while covering a lateral surface of the light-emitting element and a lateral surface of the protection element. An upper surface of the light-emitting element and an upper surface of the protection element are positioned in a same plane.

According to embodiments, a light-emitting device in which the light extraction efficiency can be increased and a method for manufacturing such a light-emitting device can be realized.

### BRIEF DESCRIPTION OF THE DRAWINGS

FIGS. 1 to 4 are cross-sectional views showing a method for manufacturing a light-emitting device according to a first embodiment;

FIG. 5 is a cross-sectional view showing the light-emitting device according to the first embodiment;

FIG. 6 is a perspective view showing the light-emitting device according to the first embodiment;

FIGS. 7 and 8 are cross-sectional views showing a method for manufacturing a light-emitting device according to a second embodiment;

FIG. 9 is a cross-sectional view showing the light-emitting device according to the second embodiment;

FIG. 10 is a cross-sectional view showing a light-emitting device according to a third embodiment;

FIG. 11 is a cross-sectional view showing a method for manufacturing a light-emitting device according to a fourth embodiment;

FIG. 12 is a cross-sectional view showing the light-emitting device according to the fourth embodiment;

FIG. 13 is a perspective view showing a light-emitting device according to a fifth embodiment;

FIG. 14 is a cross-sectional view along line XIV-XIV shown in FIG. 13;

FIG. 15 is a cross-sectional view along line XV-XV shown in FIG. 13;

FIG. 16A, FIG. 16B, and FIGS. 17A to 17C are micrographs showing appearances after polishing a light-emitting element, a protection element, and a first covering member;

FIG. 18 is a table showing measurement results of surface roughnesses of a light-emitting element, a protection element, and a first covering member; and

FIG. 19 is a graph showing a surface profile of one sample, the horizontal axis is a horizontal-direction position; and the vertical axis is the vertical-direction position.

### DETAILED DESCRIPTION

A method for manufacturing a light-emitting device and a light-emitting device according to embodiments will now be described with reference to the drawings. The drawings are schematic and conceptual, and are enhanced and simplified as appropriate. Therefore, the dimensions of the components are not necessarily an accurate representation of the actual product. The dimensional ratios, numbers, positional relationships, etc., of the components do not necessarily match between the drawings. This is similar for the other drawings described below as well. The sizes, positional relationships, etc., of the members shown in the drawings may be exaggerated for clarity of description. Furthermore, to avoid excessive complexity of the drawings, schematic views may be used in which some of the components are not illustrated; and end views may be used in which only a cross section is shown as a cross-sectional view. According to the embodiment, “covered” and “cover” are not limited to direct contact, and include the case of covering and being covered indirectly via, for example, another member.

### First Embodiment

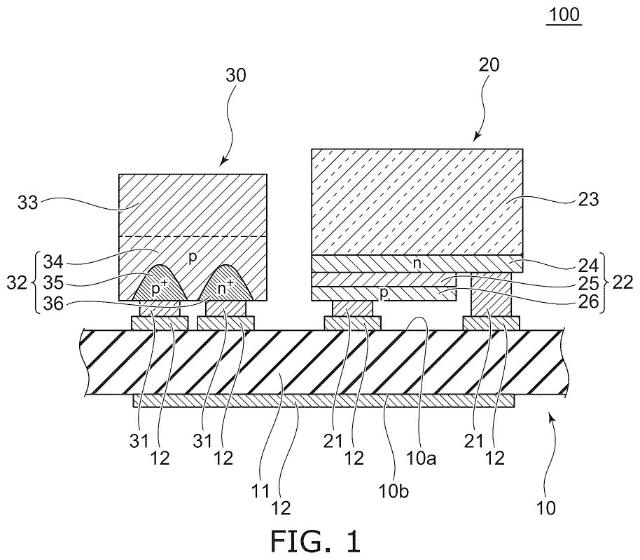

FIGS. 1 to 4 are cross-sectional views showing a method for manufacturing a light-emitting device according to the embodiment.

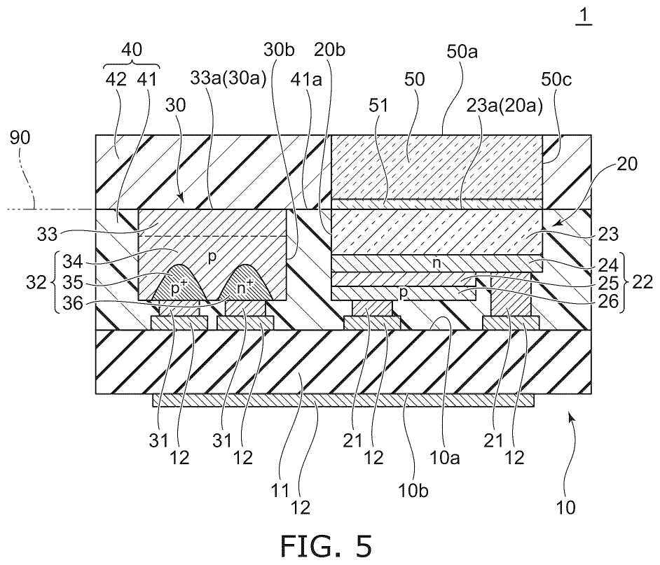

FIG. 5 is a cross-sectional view showing the light-emitting device according to the embodiment.

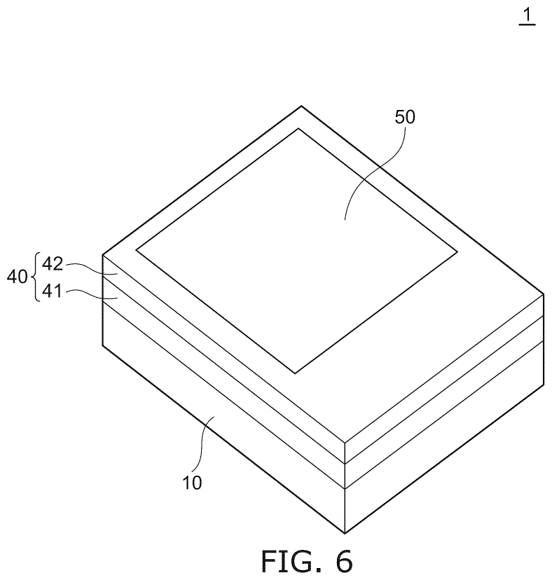

FIG. 6 is a perspective view showing the light-emitting device according to the embodiment.

### Process of Providing Structure Body 100

As shown in FIG. 1, a wiring substrate 10, a light-emitting element 20, and a protection element 30 are provided. The order in which these components are provided is arbitrary.

The wiring substrate 10 includes an insulating base body 11 and a conductive wiring part 12. The wiring part 12 is located at least at an upper surface 10a of the wiring substrate 10. In addition to the upper surface 10a of the wiring substrate 10, the wiring part 12 may be located inside the wiring substrate 10 and at a lower surface 10b of the wiring substrate 10.

The light-emitting element 20 is, for example, a light-emitting diode. The light-emitting element 20 includes a pair of first electrodes 21, a first semiconductor layer 22, and a first element substrate 23. In the light-emitting element 20, the pair of first electrodes 21, the first semiconductor layer 22, and the first element substrate 23 are stacked in this order. The first element substrate 23 is, for example, a growth substrate of the first semiconductor layer 22 and is, for example, a sapphire substrate.

In the process of providing a structure body 100 (hereinbelow, also called “the provision process”), considering ease of mounting to the wiring substrate 10, the thickness of the light-emitting element 20 to be provided is not less than 100 μm, e.g., about 150 μm. Within the thickness of the light-emitting element 20, the thickness of the first element substrate 23 is the thickness of the light-emitting element 20 minus the thickness of the first electrode 21 and the thickness of the first semiconductor layer 22, and is, for example, about 130 μm. It is sufficient for the light-emitting element 20 to include at least one positive and negative pair of first electrodes 21 at the same surface side of the light-emitting element 20; and multiple pairs of first electrodes 21 or different numbers of positive and negative first electrodes 21 may be provided at the same surface side of the light-emitting element 20. The thickness of the first electrode 21 is, for example, about 10 μm.

The first semiconductor layer 22 includes, for example, a gallium nitride (GaN) semiconductor. The thickness of the first semiconductor layer 22 is, for example, about 8 μm to 10 μm. In the first semiconductor layer 22, an n-type semiconductor layer 24, an active layer 25, and a p-type semiconductor layer 26 are stacked in this order from the first element substrate 23 side. Among the pair of first electrodes 21, one of the first electrodes 21 is connected to the n-type semiconductor layer 24; and the other of the first electrodes 21 is connected to the p-type semiconductor layer 26. In the specification, “connect” means an electrical connection.

The protection element 30 protects the light-emitting element 20 from a surge current or static electricity and is, for example, a Zener diode. The protection element 30 includes a pair of second electrodes 31, a second semiconductor layer 32, and a second element substrate 33. In the protection element 30, the pair of second electrodes 31, the second semiconductor layer 32, and the second element substrate 33 are stacked in this order. The second element substrate 33 is, for example, a semiconductor substrate and is, for example, a silicon (Si) substrate. In the provision process, considering ease of mounting to the wiring substrate 10, the thickness of the protection element 30 to be provided is not less than 100 μm, e.g., about 150 μm. The thickness of the second element substrate is, for example, about 120 μm. It is sufficient for the protection element 30 to include at least a positive and negative pair of second electrodes 31 at the same surface side of the protection element 30; and multiple pairs of second electrodes 31 or different numbers of positive and negative second electrodes 31 may be provided at the same surface side of the protection element 30. The thickness of the second electrode is, for example, about 10 μm.

The second semiconductor layer 32 includes, for example, a silicon semiconductor. The thickness of the second semiconductor layer 32 is, for example, about 20 μm. The second semiconductor layer 32 includes, for example, a base material layer 34 of the p-conductivity type, a first semiconductor region 35 of the p⁺-conductivity type, and a second semiconductor region 36 of the n⁺-conductivity type. The impurity concentration of the first semiconductor region 35 is greater than the impurity concentration of the base material layer 34. The first semiconductor region 35 and the second semiconductor region 36 are exposed at the lower surface of the base material layer 34. The second semiconductor region 36 is separated from the first semiconductor region 35 with the base material layer 34 interposed. Among the pair of second electrodes 31, one of the second electrodes 31 is connected to the first semiconductor region 35; and the other of the second electrodes 31 is connected to the second semiconductor region 36.

The light-emitting element 20 and the protection element 30 are disposed on the wiring substrate 10 after providing the wiring substrate 10, the light-emitting element 20, and the protection element 30. At this time, it is preferable for the light-emitting element 20 and the protection element 30 to have a flip-chip connection to the wiring substrate 10. In other words, the first electrodes 21 of the light-emitting element 20 are caused to face the wiring parts 12 of the wiring substrate 10; and the first electrodes 21 are bonded to the wiring parts 12. The second electrodes 31 of the protection element 30 are caused to face the wiring parts 12 of the wiring substrate 10; and the second electrodes 31 are bonded to the wiring parts 12. The order of the process of disposing the light-emitting element 20 on the wiring substrate 10 and the process of disposing the protection element 30 on the wiring substrate 10 is arbitrary.

The first electrodes 21 of the light-emitting element 20 and/or the second electrodes 31 of the protection element 30 can be connected with the wiring parts 12 of the wiring substrate 10 via a conductive bonding member. Examples of the bonding member include known bonding members such as eutectic solder, conductive paste, bumps, plating, etc. The first electrodes 21 of the light-emitting element 20 and/or the second electrodes 31 of the protection element 30 may be directly bonded with the wiring parts 12 of the wiring substrate 10 without a bonding member interposed.

Thus, the structure body 100 is provided. The structure body 100 includes the wiring substrate 10, the light-emitting element 20, and the protection element 30. On one wiring substrate 10 in the structure body 100, only one set of at least one light-emitting element 20 and at least one protection element 30 for protecting the at least one light-emitting element 20 may be included, or multiple sets may be included. FIGS. 1 to 4 show only one set of one light-emitting element 20 and one protection element 30. In the structure body 100, a pair of first electrodes 21 of the light-emitting element 20 and a pair of second electrodes 31 of the protection element 30 face the upper surface 10a of the wiring substrate 10 and are connected to the wiring parts 12.

The structure body 100 may be provided by manufacturing as described above, or may be provided by acquiring externally by procurement, etc.

### Process of Disposing First Covering Member 41

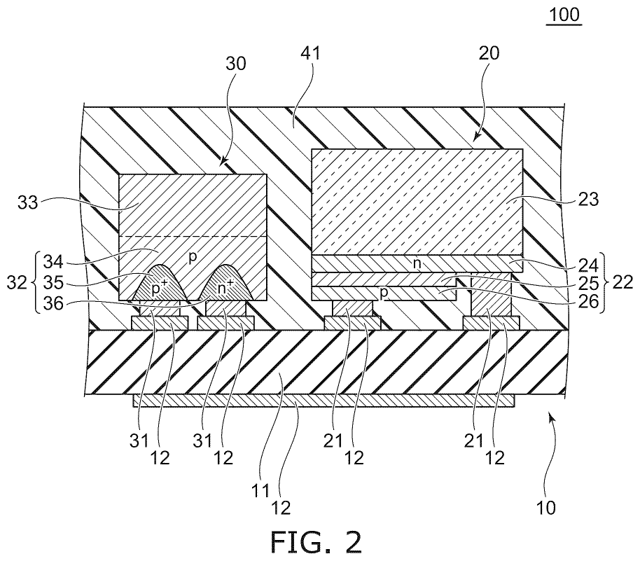

Then, as shown in FIG. 2, a first covering member 41 is disposed on the wiring substrate 10. The first covering member 41 can include, for example, a resin. Examples of the resin used for the first covering member 41 include a silicone resin. The first covering member 41 fixes the first electrodes 21 of the light-emitting element 20 and the wiring parts 12 of the wiring substrate 10, and fixes the second electrodes 31 of the protection element 30 and the wiring parts 12 of the wiring substrate 10. For example, the first covering member 41 can cover the entire light-emitting element 20 and the entire protection element 30. In other words, the first covering member 41 covers the first element substrate 23 of the light-emitting element 20 and the second element substrate 33 of the protection element 30. The first covering member 41 may be located between the wiring substrate 10 and the light-emitting element 20 and between the wiring substrate 10 and the protection element 30.

In the process of disposing the first covering member 41, an uncured resin that is used to form the first covering member 41 is disposed on the wiring substrate 10. The uncured resin for configuring the first covering member 41 can be disposed by, for example, potting, spraying, printing, transfer molding, injection molding, compression molding, etc. Subsequently, the first covering member 41 is formed by curing the resin. It is preferable for the first covering member 41 after curing to have a lower hardness than the first and second element substrates 23 and 33. As a result, in the first removal process described below, the first covering member 41 can be removed together with the light-emitting element 20 and the protection element 30; and cracking and/or chipping of the light-emitting element 20 and/or the protection element 30 can be reduced.

### First Removal Process

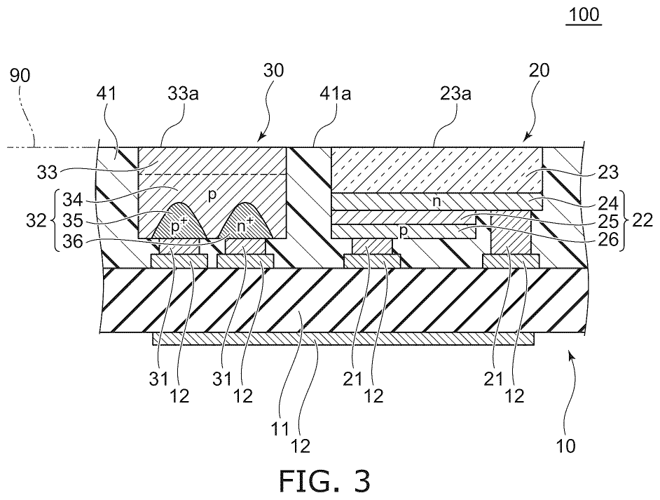

Then, as shown in FIG. 3, at least a portion of the first element substrate 23 of the light-emitting element 20 and at least a portion of the second element substrate 33 of the protection element 30 are removed from the structure body 100. Examples of the removal method include known methods such as polishing, cutting, etching, blasting, etc. Among such methods, polishing is preferable. According to the embodiment, a portion of the first element substrate 23, a portion of the second element substrate 33, and a portion of the first covering member 41 can be removed by simultaneously polishing the structure body 100 from the surface at the side opposite to the wiring substrate 10, i.e., the upper surface side of the first covering member 41. As a result, the upper surface of the first element substrate 23, the upper surface of the second element substrate 33, and the upper surface of the first covering member 41 exposed by the polishing can be in the same plane. Also, the height variation of the light-emitting element 20 and the protection element 30 between manufactured light-emitting devices can be reduced.

As a result, in the structure body 100 in which the first covering member 41 is disposed, the first element substrate 23, the second element substrate 33, and the first covering member 41 of the structure body 100 are polished from the upper surface side; and a new upper surface 23a of the first element substrate 23 and a new upper surface 33a of the second element substrate 33 are exposed from under the first covering member 41. The upper surface 23a, the upper surface 33a, and an upper surface 41a of the first covering member 41 of the structure body 100 after polishing are positioned in the same virtual plane 90. At this time, the first semiconductor layer 22 and the first electrodes 21 of the light-emitting element 20 and the second semiconductor layer 32 and the second electrodes 31 of the protection element 30 remain in the structure body 100 without being removed by the polishing. For example, the thicknesses of the light-emitting element 20, the protection element 30, and the first covering member 41 after polishing are set to be not less than 20 μm and not more than 80 μm, e.g., about 60 μm.

### Process of Disposing Light-Transmitting Member 50

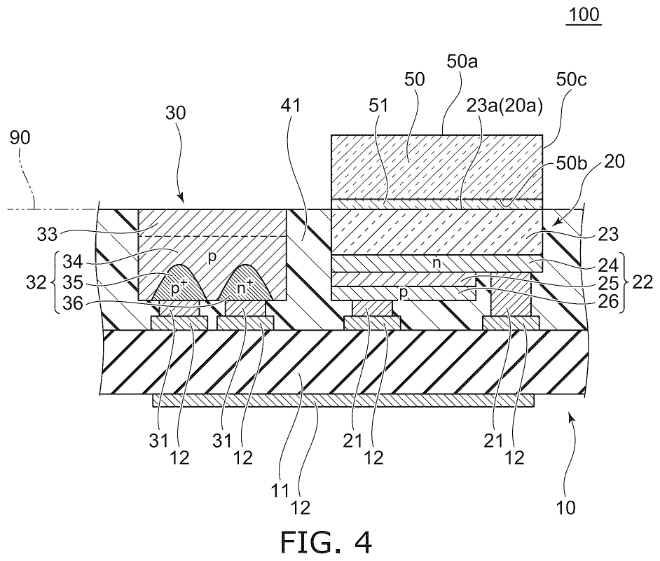

Then, as shown in FIG. 4, a light-transmitting member 50 is disposed on the light-emitting element 20 of the structure body 100. The light-transmitting member 50 is a plate-like member including an upper surface 50a, a lower surface 50b at the side opposite to the upper surface 50a, and a lateral surface 50c between the upper surface 50a and the lower surface 50b. The light-transmitting member 50 is disposed on the light-emitting element 20 so that the lower surface 50b of the light-transmitting member 50 faces an upper surface 20a of the light-emitting element 20 (here, the upper surface 23a of the first element substrate 23). For example, the light-transmitting member 50 can be bonded to the upper surface 23a of the first element substrate 23 of the light-emitting element 20 by a bonding material layer 51. The bonding material layer 51 is light-transmissive. The light-transmitting member 50 may be directly bonded to the light-emitting element 20 without the bonding material layer 51 interposed.

The area of the lower surface 50b of the light-transmitting member 50 may be equal to the area of the upper surface 20a of the light-emitting element 20, greater than the area of the upper surface 20a of the light-emitting element 20, or less than the area of the upper surface 20a of the light-emitting element. It is preferable for the area of the lower surface 50b of the light-transmitting member 50 to be not less than the area of the upper surface 20a of the light-emitting element 20, and more preferably equal to the area of the upper surface 20a of the light-emitting element 20.

By setting the entire upper surface 20a of the light-emitting element 20 to face the lower surface 50b of the light-transmitting member 50 in a plan view, greater amount of the light emitted from the light-emitting element 20 can be incident on the lower surface 50b of the light-transmitting member 50. Also, by setting the entire lower surface 50b of the light-transmitting member 50 to face the upper surface 20a of the light-emitting element 20, the light that is emitted from the upper surface 20a of the light-emitting element 20 can be perpendicularly incident on the lower surface 50b over the entire lower surface 50b of the light-transmitting member 50. As a result, uneven brightness and uneven chromaticity at the upper surface 50a, which is the light extraction surface of the light-transmitting member 50, can be reduced.

When the light-transmitting member 50 is located on the light-emitting element 20 with the bonding material layer 51 interposed, the bonding material layer 51 is located in at least the region in which the lower surface 50b of the light-transmitting member 50 and the upper surface 20a of the light-emitting element 20 face each other. It is preferable for the bonding material layer 51 to cover the entire upper surface 20a of the light-emitting element 20 and the entire lower surface 50b of the light-transmitting member 50 in a plan view. As a result, greater amount of the light emitted from the light-emitting element 20 can be incident on the lower surface 50b of the light-transmitting member 50 via the bonding material layer 51.

The light-transmitting member 50 includes, for example, a phosphor. The phosphor absorbs the light emitted from the light-emitting element 20 and emits light of a different wavelength. According to the embodiment, the light-transmitting member 50 is a plate-shaped ceramic containing a phosphor, and is, for example, a sintered body of a YAG (yttrium aluminum garnet) phosphor and aluminum oxide (Al₂O₃). However, as described below, the configuration of the light-transmitting member 50 is not limited thereto.

### Process of Disposing Second Covering Member 42

Then, as shown in FIG. 5, a second covering member 42 is disposed on the first covering member 41. For example, the second covering member 42 can be disposed using potting, spraying, printing, compression molding using a mold, etc. The second covering member 42 covers an upper surface 30a of the protection element 30 and the lateral surface 50c of the light-transmitting member 50 and does not cover the upper surface 50a of the light-transmitting member 50. The second covering member 42 is, for example, a resin material and includes, for example, a silicone resin. The second covering member 42 covers the lateral surface 50c of the light-transmitting member 50 that is included in the light-emitting surface of the light-emitting device 1. It is therefore preferable for the second covering member 42 to have a higher reflectance for the light emitted from the light-emitting element 20 than the first covering member 41. As a result, leakage light from the upper surface of the second covering member 42 among the light emitted from the light-emitting element 20 can be reduced.

Continuing, the wiring substrate 10 and a covering member 40 are singulated into each set including one light-emitting element 20 and one protection element 30. Thus, the light-emitting device 1 according to the embodiment is manufactured. In the light-emitting device 1, the first covering member 41 and the second covering member 42 configure the covering member 40 of the light-emitting device 1. The light-emitting device 1 may have a configuration that does not include the second covering member 42.

### Light-Emitting Device 1

A configuration of the light-emitting device 1 will now be described.

As shown in FIGS. 5 and 6, the light-emitting device 1 includes the wiring substrate 10, the light-emitting element 20, the protection element 30, the covering member 40, and the light-transmitting member 50. The light-emitting element 20, the protection element 30, and the covering member 40 each are located on the wiring substrate 10. The light-transmitting member 50 is located on the light-emitting element 20. The covering member 40 covers a lateral surface 20b of the light-emitting element 20 and the upper surface 30a and a lateral surface 30b of the protection element 30, but does not cover the upper surface 50a of the light-transmitting member 50. The upper surface 20a of the light-emitting element 20 and the upper surface 30a of the protection element 30 are positioned in the same plane 90. In the specification, “in the same plane” means that the allowed variation is such that the difference between the surfaces is within ±15 μm.

The wiring substrate 10 includes the insulating base body 11 and the conductive wiring part 12. The wiring part 12 is located on at least the upper surface 10a of the wiring substrate 10. The wiring part 12 may include an anode pad and a cathode pad as external connection terminals connected outside the light-emitting device 1 at the upper surface 10a or the lower surface 10b of the wiring substrate 10.

The light-emitting element 20 includes the pair of first electrodes 21, the first semiconductor layer 22, and the first element substrate 23. The first electrodes 21 are connected to the wiring parts 12 of the wiring substrate 10. The first semiconductor layer 22 includes, for example, a gallium nitride semiconductor. In the first semiconductor layer 22, the p-type semiconductor layer 26, the active layer 25, and the n-type semiconductor layer 24 are provided in this order from the wiring substrate 10 side. The p-type semiconductor layer 26 and the n-type semiconductor layer 24 are connected respectively to the first electrodes 21 of different polarities. The first element substrate 23 is light-transmissive. The first element substrate 23 is, for example, a sapphire substrate. The lower surface of the first element substrate 23 contacts the n-type semiconductor layer 24. The upper surface 23a of the first element substrate 23 forms the upper surface 20a of the light-emitting element 20.

In the light-emitting device 1, the thickness of the light-emitting element 20 is, for example, not less than 20 μm and not more than 80 μm, e.g., about 60 μm. Within the light-emitting element 20, for example, the thickness of the first semiconductor layer 22 is about 8 to 10 μm; and the thickness of the first electrode 21 is about 10 μm. By thinning the light-emitting element 20, the light that is emitted laterally from the lateral surface of the light-emitting element 20, passes through the covering member 40, and leaks outside the light-emitting device 1 can be reduced.

In the first semiconductor layer 22, the active layer 25 may have a single quantum well (SQW) structure, or may have a multi-quantum well (MQW) structure including multiple well layers. The first semiconductor layer 22 includes multiple semiconductor layers formed of a nitride semiconductor. The nitride semiconductor all includes compositions of semiconductors of the chemical formula InₓAl_{y}Ga_{1-x-y}N (0≤x, 0≤y, and x+y≤1) for which the composition ratios x and y are changed within the ranges respectively. The light emission peak wavelength of the active layer can be selected as appropriate according to the purpose. For example, the active layer is configured to emit visible light or ultraviolet light.

The first semiconductor layer 22 may include multiple light-emitting parts formed of the n-type semiconductor layer 24, the active layer 25, and the p-type semiconductor layer 26. When the first semiconductor layer 22 includes multiple light-emitting parts, each of the light-emitting parts may include well layers having different light emission peak wavelengths, or may include well layers having the same light emission peak wavelength. The light emission peak wavelength being the same also includes cases where there is variation of about several nm. The combination of the light emission peak wavelengths of the multiple light-emitting parts can be selected as appropriate. For example, when the first semiconductor layer includes two light-emitting parts, examples of combinations of the light emitted by the light-emitting parts include blue light and blue light, green light and green light, red light and red light, ultraviolet light and ultraviolet light, blue light and green light, blue light and red light, green light and red light, etc. For example, when the semiconductor structure body includes three light-emitting parts, examples of the combinations of the light emitted by the light-emitting parts include blue light, green light, and red light. Each light-emitting part may include one or more well layers having different light emission peak wavelengths than the other well layers.

The light-emitting device 1 includes the protection element 30. Examples of the protection element 30 include a Zener diode, a varistor, a capacitor, etc. By the light-emitting device 1 including the protection element 30, a reverse voltage applied to the light-emitting element 20 can be shorted, and forward overvoltage applied to the light-emitting element 20 can be shorted. The protection element 30 is, for example, a bare-chip Zener diode. From the perspective of protecting the light-emitting element 20 from overvoltage, it is preferable for the range of the Zener voltage to be about 16 to 40 V.

The protection element 30 includes the pair of second electrodes 31, the second semiconductor layer 32, and the second element substrate 33. The second electrodes 31 are connected to the wiring parts 12 of the wiring substrate 10. The second element substrate 33 is, for example, a semiconductor substrate. The semiconductor substrate may be an intrinsic semiconductor that substantially does not include an impurity, or may be a p-type or n-type semiconductor substrate doped with a p-type impurity or an n-type impurity. For example, the second element substrate 33 is a p-type silicon semiconductor substrate.

The second semiconductor layer 32 is, for example, a silicon semiconductor that includes, for example, the base material layer 34 of the p-conductivity type and the first semiconductor region 35 and the second semiconductor region 36 arranged to be separated from each other inside the base material layer 34. The conductivity type of the first semiconductor region 35 is the p⁺-type; and the conductivity type of the second semiconductor region 36 is the n⁺-type. The first semiconductor region 35 and the second semiconductor region 36 are connected to the second electrodes 31 having respectively different polarities. The lower surface of the second element substrate 33 contacts the base material layer 34. The upper surface 33a of the second element substrate 33 forms the upper surface 30a of the protection element 30. The thickness of the second semiconductor layer 32 is, for example, about 20 μm.

In the protection element 30, the second element substrate 33 and the base material layer 34 of the second semiconductor layer 32 may be formed of different materials, or may be formed of the same material. When the second element substrate 33 and the base material layer 34 of the second semiconductor layer 32 are formed of the same material (e.g., a silicon semiconductor), there are cases where a distinct boundary is not present between the second element substrate 33 and the second semiconductor layer. Even when there is a boundary, there are cases where it is not easy to visually recognize the boundary. In the drawings, the boundary between the second element substrate 33 and the second semiconductor layer 32 is illustrated by a broken line.

In the light-emitting device 1, the thickness of the protection element 30 is, for example, about 60 μm. The thickness of the second element substrate 33 is, for example, about 30 μm; the thickness of the second semiconductor layer 32 is, for example, about 20 μm; and the thickness of the second electrode 31 is, for example, about 10 μm.

The covering member 40 is located on the wiring substrate 10, covers the lateral surface 20b of the light-emitting element 20 and the lateral surface 30b of the protection element 30, and does not cover the upper surface 50a of the light-transmitting member 50. The upper surface 30a of the protection element 30 may be covered with the covering member 40 or may be exposed from the covering member 40. When the second element substrate 33 is a semiconductor substrate, it is preferable for the upper surface 30a of the protection element 30 to be covered with the covering member 40. The covering member 40 is preferably formed of an insulating material. The covering member 40 preferably has light-shielding property, and more preferably light-reflective property. The covering member 40 is, for example, a member in which particles of a light-reflective substance or the like are contained in a light-transmitting resin.

Examples of the resin included in the covering member 40 include a silicone resin, a modified silicone resin, an epoxy resin, a modified epoxy resin, a polyester resin, a polyimide resin, a modified polyimide resin, etc. It is preferable to use a thermosetting resin having good heat resistance; for example, a silicone resin that has good weather resistance can be used preferably. Examples of the light-reflective substance include titanium oxide, zirconium oxide, boron nitride, and aluminum oxide. The covering member 40 may include an organic material such as a resin or the like, an inorganic material, or both an organic material and an inorganic material. For example, the covering member 40 may include an inorganic material including boron nitride and alkali metal silicate.

The light-emitting device 1 can include the first covering member 41 and the second covering member 42 as the covering member 40. The first covering member 41 contacts the wiring substrate 10 and covers the lateral surface 20b of the light-emitting element 20 and the lateral surface 30b of the protection element 30. The upper surface 41a of the first covering member 41 is positioned in a plane 90. The second covering member 42 is located on the first covering member 41. The second covering member 42 covers the upper surface 30a of the protection element 30 and the lateral surface 50c of the light-transmitting member 50. It is preferable for the second covering member 42 to have a higher reflectance for the light emitted from the light-emitting element 20 than the first covering member 41.

It is preferable for the surface roughness (Sa) of the upper surface 30a of the protection element 30 to be greater than the surface roughness (Sa) of the upper surface 20a of the light-emitting element 20. The adhesion between the protection element 30 and the second covering member 42 is improved thereby. Also, it is preferable for the surface roughness (Sa) of the upper surface 41a of the first covering member 41 to be greater than the surface roughness (Sa) of the upper surface 20a of the light-emitting element 20 and the surface roughness (Sa) of the upper surface 30a of the protection element 30. The adhesion between the first covering member 41 and the second covering member 42 is improved thereby.

The light-transmitting member 50 is located on the light-emitting element 20, transmits the light emitted from the light-emitting element 20, and emits the light externally. For example, the light-transmitting member 50 is bonded to the first element substrate 23 of the light-emitting element 20 via the light-transmitting bonding material layer 51.

For example, the light-transmitting member 50 may be formed of any or at least one selected from the group consisting of inorganic material such as a ceramic such as aluminum nitride, aluminum oxide, yttrium oxide, yttrium aluminum perovskite (YAlO₃: YAP), or the like, glass, sapphire, or the like, or an organic material such as a resin including at least one of a silicone resin, a modified silicone resin, an epoxy resin, a modified epoxy resin, an acrylic resin, a phenol resin, a fluororesin, a hybrid resin, etc.

The light-transmitting member 50 may include a phosphor configured to convert at least a portion of the light emitted by the light-emitting element 20 into light of a different wavelength. Examples of the light-transmitting member 50 containing the phosphor include a sintered body of a phosphor, and a member including a light-transmitting base material such as a resin, a glass, a ceramic, etc., in which phosphor powder is contained. The sintered body of the phosphor may be formed by sintering only a phosphor, or may be formed by sintering a mixture of a phosphor and a substance (e.g., a light-diffusing substance, a sintering aid, etc.) other than a phosphor. The light-transmitting member 50 may include a member in which a phosphor layer is located at the surface of a light-transmitting base body such as a resin, glass, a ceramic, etc.

Examples of the phosphor include oxynitride-based phosphors such as an yttrium-aluminum-garnet-based phosphor (e.g., (Y, Gd)₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂:Eu), an SAE-based phosphor (e.g., Sr₄Al₁₄O₂₅:Eu), a chlorosilicate-based phosphor (e.g., Ca₈MgSi₄O₁₆Cl₂:Eu), a silicate-based phosphor (e.g., (Ba, Sr, Ca, Mg)₂SiO₄:Eu), a β-sialon-based phosphor (e.g., (Si, Al)₃(O, N)₄:Eu), an α-sialon-based phosphor (e.g., Ca(Si, Al)₁₂(O, N)₁₆:Eu), or the like, nitride-based phosphors such as an LSN-based phosphor (e.g., (La, Y)₃Si₆N₁₁:Ce), a BSESN-based phosphor (e.g., (Ba, Sr)₂Si₅N₈:Eu), an SLA-based phosphor (e.g., SrLiAl₃N₄:Eu), a CASN-based phosphor (e.g., CaAlSiN₃:Eu), a SCASN-based phosphor (e.g., (Sr, Ca) AlSiN₃:Eu), or the like, fluoride-based phosphors such as a KSF-based phosphor (e.g., K₂SiF₆:Mn), a KSAF-based phosphor (e.g., K₂ (Si₁₋ₓAlₓ)F₆₋ₓ:Mn, wherein x satisfies 0<x<1), a MGF-based phosphor (e.g., 3.5MgO·0.5MgF₂·GeO₂:Mn), or the like, a quantum dot having a perovskite structure (e.g., (Cs, FA, MA)(Pb, Sn)(F, Cl, Br, I)₃, wherein FA and MA are respectively formamidinium and methylammonium), a Group II-VI quantum dot (e.g., CdSe), a Group III-V quantum dot (e.g., InP), a quantum dot having a chalcopyrite structure (e.g., (Ag, Cu)(In, Ga)(S, Se)₂), etc.

The light-transmitting member 50 may include a filler such as a light-diffusing substance, etc. Examples of the light-diffusing substance include titanium oxide, barium titanate, aluminum oxide, YAP (yttrium aluminum perovskite), and silicon oxide. However, the light-diffusing substance is not limited thereto. The light-transmitting member 50 may include an optical film such as an anti-reflection coating or the like on the upper surface, and may include an optical film such as a reflective film or the like at the lateral surface. The light-emitting device 1 may include the light-transmitting adhesive layer 51 such as a silicone resin or the like between the light-transmitting member 50 and the light-emitting element 20.

When a voltage from the outside is applied via the anode and cathode pads of the light-emitting device 1, a DC voltage is applied between the p-type semiconductor layer 26 and the n-type semiconductor layer 24 of the first semiconductor layer 22 via the pair of first electrodes 21 of the light-emitting element 20; and the active layer 25 emits, for example, blue light. The blue light that is emitted from the active layer 25 passes through the n-type semiconductor layer 24, the first element substrate 23, and the bonding material layer 51 and is incident on the light-transmitting member 50. The light-transmitting member 50 includes, for example, a phosphor that absorbs a portion of the incident blue light and emits yellow light. As a result, the light-emitting device 1 can emit white light in which the yellow light and the blue light from the light-transmitting member 50 are mixed. When a reverse surge current flows into the light-emitting device 1 due to static electricity, etc., the protection element 30 can protect the light-emitting element 20 from the surge current by carrying the surge current.

### Effects

According to the embodiment, the process of removing the first element substrate 23 and the second element substrate 33 from the structure body 100 shown in FIG. 3 (hereinbelow, also called “the removal process”) includes removing a portion of the first element substrate 23 of the light-emitting element 20 and a portion of the second element substrate 33 of the protection element 30. Therefore, the thickness of the light-emitting element 20 (specifically, the thickness of the first element substrate 23) can be thinned. As a result, the amount of the light emitted from the first semiconductor layer 22 that is emitted laterally from the lateral surface of the first element substrate 23 can be reduced. As a result, the light extraction efficiency of the light-emitting device 1 is increased. Because the thickness of the protection element 30 (specifically, the thickness of the second element substrate 33) also can be thinned, the light from the light-emitting element 20 that is absorbed by the protection element 30 can be reduced. The light extraction efficiency of the light-emitting device 1 is increased thereby.

According to the embodiment, the light-emitting element 20 and the protection element 30 are disposed on the wiring substrate 10 in the process of providing the structure body before the light-emitting element 20 and the protection element 30 are thinned in the removal process. It is therefore easy to handle the light-emitting element 20 and the protection element 30 in the process of disposing the light-emitting element 20 and the protection element 30 on the wiring substrate 10. According to the embodiment, the thicknesses of the light-emitting element 20 and the protection element 30 after their portions are removed in the removal process are, for example, about 60 μm. If the light-emitting element 20 and the protection element 30 were to be pre-processed to such a thickness and then disposed on the wiring substrate 10, there is a possibility that the light-emitting element 20 and the protection element 30 would be damaged by stress when disposing.

According to the embodiment, the first covering member 41 is disposed on the wiring substrate 10 in the process of disposing the first covering member. As a result, the light-emitting element 20 and the protection element 30 are fixed with respect to the wiring substrate 10, and therefore the polishing is easy in the removal process.

According to the embodiment, it is sufficient for the first covering member 41 to cover at least the lateral surfaces of the first electrode 21 of the light-emitting element 20 and the wiring part 12 of the wiring substrate 10 and the lateral surfaces of the second electrode 31 of the protection element 30 and the wiring part 12 of the wiring substrate 10 in the process of disposing the first covering member 41. As a result, detachment of the light-emitting element 20 and the protection element 30 from the wiring substrate 10 in the removal process can be reduced. In such a case, when the first electrodes 21 of the light-emitting element 20 and/or the second electrodes 31 of the protection element 30 are connected to the wiring parts 12 of the wiring substrate 10 via a bonding member, the first covering member 41 covers the lateral surface of the bonding member.

In the process of disposing the first covering member 41, it is preferable for the first covering member 41 to cover the lateral surface of the light-emitting element 20 and the lateral surface of the protection element 30; and it is more preferable for the first covering member 41 to collectively cover the upper surface of the light-emitting element 20 and the upper surface of the protection element 30 as shown in FIG. 2. As a result, damage such as cracking, chipping, etc., of the light-emitting element 20 and/or the protection element 30 in the first removal process can be reduced.

In the removal process according to the embodiment, only a portion of the second element substrate 33 of the protection element 30 is removed, and the entire second semiconductor layer 32 remains. As a result, the Zener voltage of the protection element 30 can be maintained.

In the process of disposing the second covering member according to the embodiment, the second covering member 42 is disposed on the first covering member 41 to cover the lateral surface 50c of the light-transmitting member 50 but to leave the upper surface 50a of the light-transmitting member 50 exposed. As a result, the light that is emitted from the lateral surface 50c of the light-transmitting member 50 can be reflected by the second covering member 42 toward the light-transmitting member 50 and emitted from the upper surface 50a of the light-transmitting member 50. As a result, the light extraction efficiency is increased. By setting the reflectance of the second covering member 42 for the light emitted from the light-emitting element 20 to be greater than the reflectance of the first covering member 41 for the light emitted from the light-emitting element 20, the light extraction efficiency is improved even further.

In the removal process according to the embodiment, a portion of the first element substrate 23, a portion of the second element substrate 33, and a portion of the first covering member 41 are removed by polishing the structure body 100 from the surface at the side opposite to the wiring substrate 10. As a result, the upper surface 23a of the first element substrate 23, the upper surface 33a of the second element substrate 33, and the upper surface 41a of the first covering member 41 can be positioned in the same plane 90. As a result, the light emitted from the upper surface of the light-emitting element 20 of the light-emitting device 1 can be suppressed from being absorbed by the protection element 30 can be reduced, and the light-emitting device can have a high light extraction efficiency. Also, the light-emitting device 1 can be smaller.

### Second Embodiment

The second embodiment differs from the first embodiment in that, after the first removal process, the remaining portion of the first covering member 41 is removed, and a covering member is newly disposed. For example, a thermoplastic polyimide resin is used as the first covering member 41.

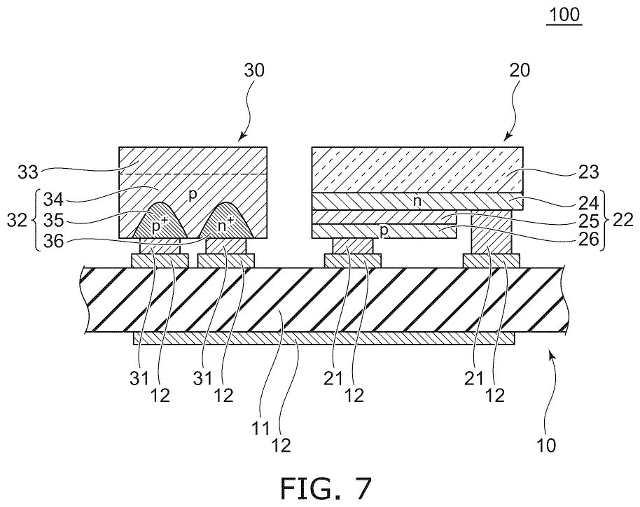

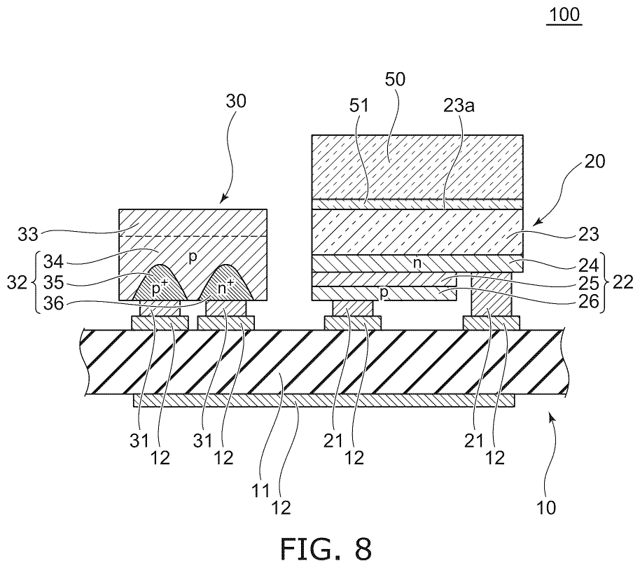

FIGS. 7 and 8 are cross-sectional views showing a method for manufacturing a light-emitting device according to the embodiment.

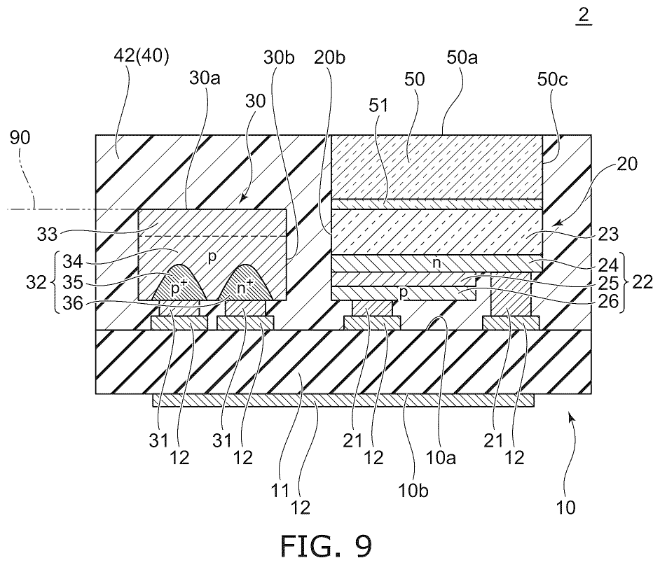

FIG. 9 is a cross-sectional view showing the light-emitting device according to the embodiment.

First, as shown in FIGS. 1 to 3, the process of providing the structure body, the process of disposing the first covering member, and the first removal process are performed.

### Second Removal Process

Then, as shown in FIG. 7, the remaining portion of the first covering member 41 is removed. At this time, the wiring substrate 10, the light-emitting element 20, and the protection element 30 remain. For example, only the first covering member 41 is removed by dissolving with an organic solvent such as cyclopentanone, etc.

### Process of Disposing Light-Transmitting Member 50

Continuing as shown in FIG. 8, the light-transmitting member 50 is disposed on the light-emitting element 20. For example, the light-transmitting member 50 is bonded to the upper surface 23a of the first element substrate 23 of the light-emitting element 20 via the bonding material layer 51.

### Process of Disposing Second Covering Member 42

Then, as shown in FIG. 9, the second covering member 42 is disposed on the wiring substrate 10. For example, the second covering member 42 can be disposed by potting, spraying, printing, transfer molding, injection molding, compression molding, etc. The second covering member 42 covers the upper surface 30a and the lateral surface 30b of the protection element 30, the lateral surface 20b of the light-emitting element 20, and the lateral surface 50c of the light-transmitting member 50, but does not cover the upper surface 50a of the light-transmitting member 50. The second covering member 42 may intrude between the wiring substrate 10 and the light-emitting element 20 and between the wiring substrate 10 and the protection element 30. For example, the second covering member 42 is formed of a resin material, e.g., a white resin material such as a silicone resin containing light-reflective particles. The second covering member 42 may be formed as a single layer or as multiple layers.

The second embodiment may include a process of disposing under-fill at the lower surface of the light-emitting element 20 and the upper surface of the wiring substrate 10 after the second removal process and before the process of disposing the second covering member 42. A resin material same as or similar to the second covering member 42 can be used as the under-fill.

Then, the wiring substrate 10 and the second covering member 42 are singulated into each set including one light-emitting element 20 and one protection element 30. Thus, the light-emitting device 2 according to the second embodiment is manufactured.

### Light-Emitting Device 2

As shown in FIG. 9, the light-emitting device 2 according to the second embodiment includes the light-emitting element 20 and the protection element 30 located on the wiring substrate 10; and the upper surface of the light-emitting element 20 and the upper surface of the protection element 30 are positioned in the same plane. The light-emitting device 2 differs from the light-emitting device 1 shown in FIG. 5 in that the first covering member 41 that is positioned in the same plane as the upper surface of the light-emitting element 20 and the upper surface of the protection element 30 is not included. In the light-emitting device 2, the covering member 40 includes only the second covering member 42.

### Effects

According to the second embodiment, the light-emitting element 20, the protection element 30, and the first covering member 41 are polished in the process shown in FIG. 3, then the remaining portion of the first covering member 41 is removed in the process shown in FIG. 7, and the second covering member 42 is deposited in the process shown in FIG. 9. As a result, the first covering member 41 does not remain in the light-emitting device 2 after manufacturing, and so the material of the first covering member 41 can be selected by considering only the ability to fix the light-emitting element 20 and the protection element 30 to the wiring substrate 10. For example, specifically, a hard resin material such as a polyimide resin can be used as the material of the first covering member 41. On the other hand, similarly to the first embodiment, a material selected with priority on the light reflectance and the heat resistance such as, for example, a white resin material such as a silicone resin can be used as the second covering member 42. Thus, suitable materials can be selected as the materials of the first and second covering members 41 and 42.

According to the second embodiment as well, it is preferable for the second covering member 42 to formed of a material having a higher reflectance for the light emitted from the light-emitting element 20. Otherwise, the manufacturing method, the configuration, and the effects according to the second embodiment are the same as or similar to those of the first embodiment.

### Third Embodiment

The configuration of the light-transmitting member according to the third embodiment is different from that of the first embodiment.

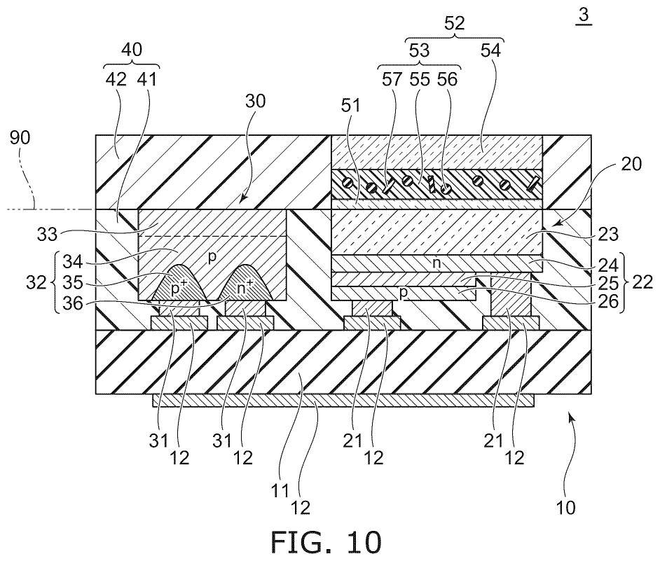

FIG. 10 is a cross-sectional view showing a light-emitting device according to the embodiment.

According to the embodiment as shown in FIG. 10, the light-emitting device 3 includes a light-transmitting member 52 instead of the light-transmitting member 50. The light-transmitting member 52 includes a resin layer 53 and a glass layer 54. The glass layer 54 is located on the resin layer 53. In the resin layer 53, for example, a phosphor 56 and/or a light-diffusing member 57 are located inside a base material 55 formed of a resin material such as silicone, etc. At least one of the phosphor 56 or the light-diffusing member 57 may not be included. The glass layer 54 may be formed of a light-transmitting material (e.g., a resin or a ceramic) other than glass.

According to the third embodiment, light of the desired color can be emitted by adjusting the type of the phosphor 56 and/or the type of the light-diffusing member 57 contained in the resin layer 53, etc. When manufacturing light-emitting devices that emit light of different colors, there are cases where the thickness of the resin layer 53 necessary for emitting the desired color is modified. However, according to the third embodiment, the light-emitting devices that emit light of different colors can be manufactured to have the same size by adjusting the thickness ratio of the resin layer 53 and the glass layer 54 in the light-transmitting member 52. Also, because the phosphor 56 is not exposed outside the light-emitting device 3, degradation of the phosphor 56 due to moisture in ambient air can be reduced. As a result, the reliability of the light-emitting device 3 is increased. Otherwise, the manufacturing method, the configuration, and the effects according to the third embodiment are the same as or similar to those of the first embodiment.

### Fourth Embodiment

The fourth embodiment differs from the first embodiment in that the first element substrate and the second element substrate do not remain.

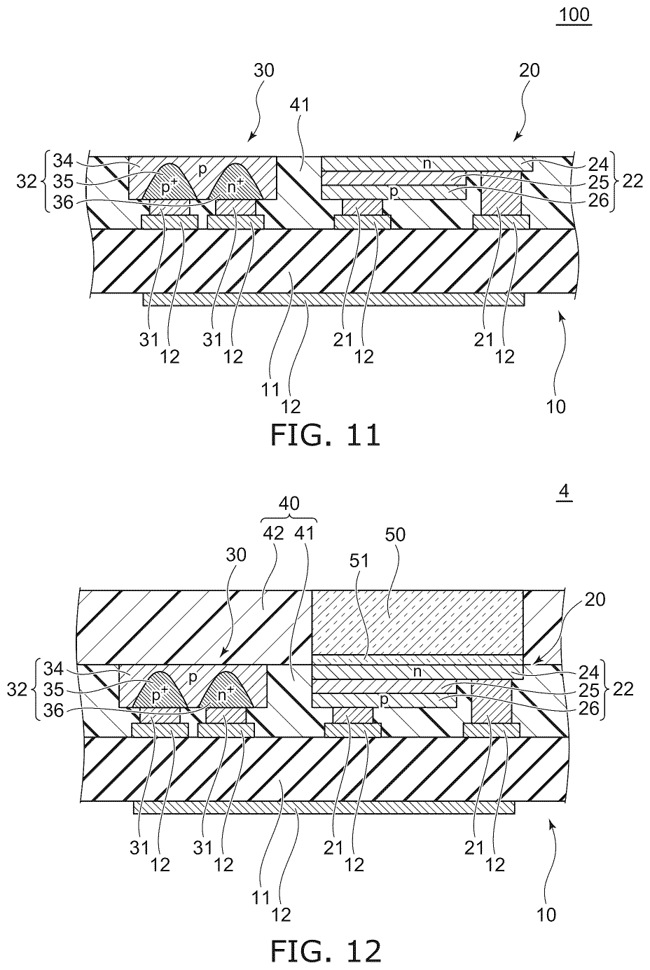

FIG. 11 is a cross-sectional view showing a method for manufacturing a light-emitting device according to the embodiment.

FIG. 12 is a cross-sectional view showing the light-emitting device according to the embodiment.

First, the processes shown in FIGS. 1 and 2 are performed.

Then, as shown in FIG. 11, the structure body 100 is polished from the surface at the side opposite to the wiring substrate 10. At this time, the entire first element substrate 23 of the light-emitting element 20 is removed, and a portion of the n-type semiconductor layer 24 of the first semiconductor layer 22 is removed. Also, the entire second element substrate 33 of the protection element 30 is removed, and a portion of the base material layer 34 of the second semiconductor layer 32 is removed.

Continuing, processes same as or similar to the processes shown in FIGS. 4 and 5 are performed.

As a result, as shown in FIG. 12, the light-emitting device 4 according to the fourth embodiment is manufactured. In the light-emitting device 4, the thicknesses of the light-emitting element 20, the protection element 30, and the first covering member 41 are, for example, about 20 μm.

As shown in FIG. 12, the light-emitting device 4 differs from the light-emitting device 1 according to the first embodiment in that the first element substrate 23 and the second element substrate 33 are not included, and the n-type semiconductor layer 24 and the base material layer 34 are thin. As a result, the light from the active layer 25 that is absorbed by the n-type semiconductor layer 24 is reduced; and the light that is emitted from the active layer 25 is not absorbed by the first element substrate 23. Furthermore, the light that is emitted from the active layer 25 is not absorbed by the second element substrate 33. As a result, the light extraction efficiency is improved even further. The light-emitting device 4 can be even smaller. Otherwise, the manufacturing method, the configuration, and the effects according to the embodiment are the same as or similar to those of the first embodiment.

### Fifth Embodiment

The fifth embodiment is an example in which multiple pairs of the light-emitting element and the protection element are included in one light-emitting device.

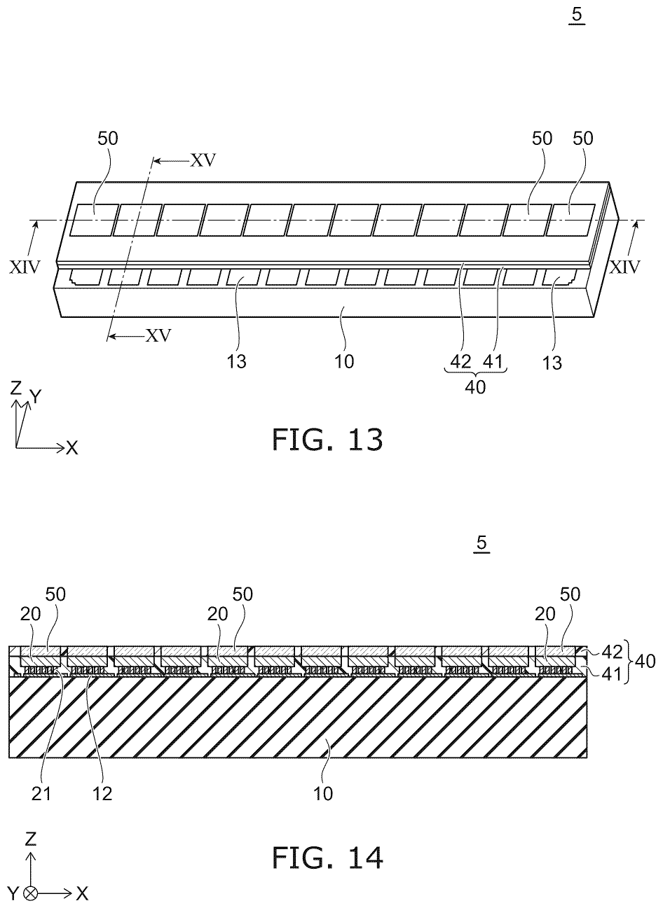

FIG. 13 is a perspective view showing a light-emitting device according to the embodiment.

FIG. 14 is a cross-sectional view along line XIV-XIV shown in FIG. 13.

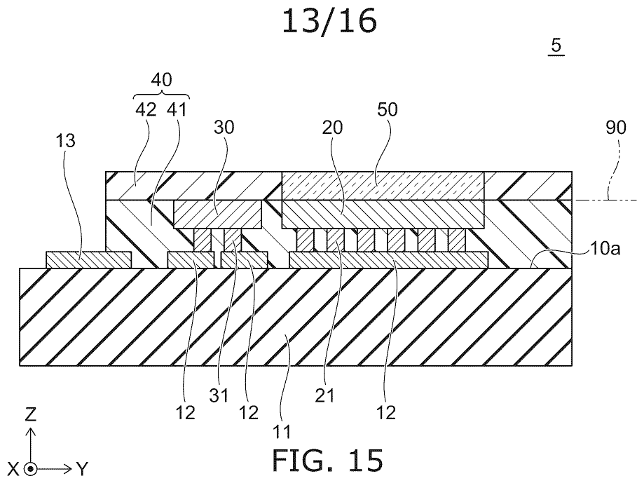

FIG. 15 is a cross-sectional view along line XV-XV shown in FIG. 13.

In the light-emitting device 5 according to the embodiment as shown in FIGS. 13 to 15, multiple pairs of the light-emitting element 20 and the protection element 30 are located on one wiring substrate 10. Multiple pads 13 that are used as external connection terminals of the light-emitting device 5 are located at the upper surface 10a of the wiring substrate 10.

In the light-emitting device 5, for example, the multiple light-emitting elements 20 are periodically arranged in one column. According to the fifth embodiment, the arrangement direction of the light-emitting element 20 is taken as an “X-direction”. A direction that is parallel to the upper surface 10a and orthogonal to the X-direction is taken as a “Y-direction”; and a direction that is orthogonal to the upper surface 10a is taken as a “Z-direction”.

In the light-emitting device 5, for example, the multiple protection elements 30 are also periodically arranged in one column along the X-direction. The number of the protection elements 30 is equal to the number of the light-emitting elements 20. For example, the multiple pads 13 are also periodically arranged in one column along the X-direction. The number of the pads 13 is one greater than the number of the light-emitting elements 20. In other words, when the number of the light-emitting elements 20 is n, the number of the protection elements 30 is n, and the number of the pads 13 is (n+1). In the example shown in FIGS. 13 to 15, n is 12.

In an example, the (n+1) pads 13 arranged in one column connect the n light-emitting element 20 in series. The light-emitting device 5 can individually drive the light-emitting elements 20 by using the (n+1) pads 13 as external connection terminals. The protection elements 30 are connected one-to-one with the light-emitting elements 20. In the Y-direction, the column of the protection elements 30 is positioned between the column of the light-emitting elements 20 and the column of the pads 13.

Similarly to the first embodiment, the light-emitting element 20 includes the first element substrate 23. The first element substrate 23 is, for example, a sapphire substrate; and the fissility of sapphire can be utilized when singulating. Therefore, in the light-emitting element 20 after singulation, there are cases where the lateral surface of the first element substrate 23 includes surfaces that are not orthogonal to the upper surface 23a due to the fissility of the first element substrate 23. When the lateral surface of the first element substrate 23 is not orthogonal to the upper surface 23a, for example, there are cases where the shape of the first element substrate 23 when viewed along the Y-direction is parallelogram-shaped instead of rectangular; and the position of the lower surface and the position of the upper surface 23a of the first element substrate 23 are misaligned in the X-direction. Due to this misalignment, in the light-emitting device 5 that includes the multiple light-emitting elements 20, there is a possibility that the distance between adjacent light-emitting elements 20 may vary.

In contrast, according to the embodiment, the first element substrate 23 is made thin in the process shown in FIG. 3, and therefore the misalignment amount between the position of the lower surface and the position of the upper surface 23a of the first element substrate 23 in the X-direction is reduced. As a result, the variation of the distances between the adjacent light-emitting elements 20 can be reduced.

For example, the light-emitting device 5 can be utilized as a light source of an automobile headlamp. For example, an ADB (adaptive driving beam) can be realized by independently controlling the multiple light-emitting elements 20. Otherwise, the manufacturing method, the configuration, and the effects according to the fifth embodiment are the same as similar to those of the first embodiment.

### TEST EXAMPLES

Test examples for the method for manufacturing the light-emitting device according to the first embodiment above will now be described in which the appearances of the upper surface 20a of the light-emitting element 20, the upper surface 30a of the protection element 30, and the upper surface 41a of the first covering member 41 were observed, and the roughnesses were measured.

According to the test examples, multiple samples were provided, and the process of providing the structure body 100 shown in FIG. 1, the process of disposing of the first covering member 41 shown in FIG. 2, and the first removal process shown in FIG. 3 were performed. In the structure body 100, the first support substrate was a sapphire substrate; and the second support substrate was a silicon substrate. In the disposition process, a silicone resin that included titanium oxide was disposed as the first covering member. To polish sapphire in the first removal process, a grindstone having a diamond abrasive and a grit of 6,000 was used to polish the upper surfaces of the samples. The upper surface 20a of the light-emitting element 20, the upper surface 30a of the protection element 30, and the upper surface 41a of the first covering member 41 were simultaneously polished thereby. Then, the surfaces of the samples after polishing were observed using an optical microscope.

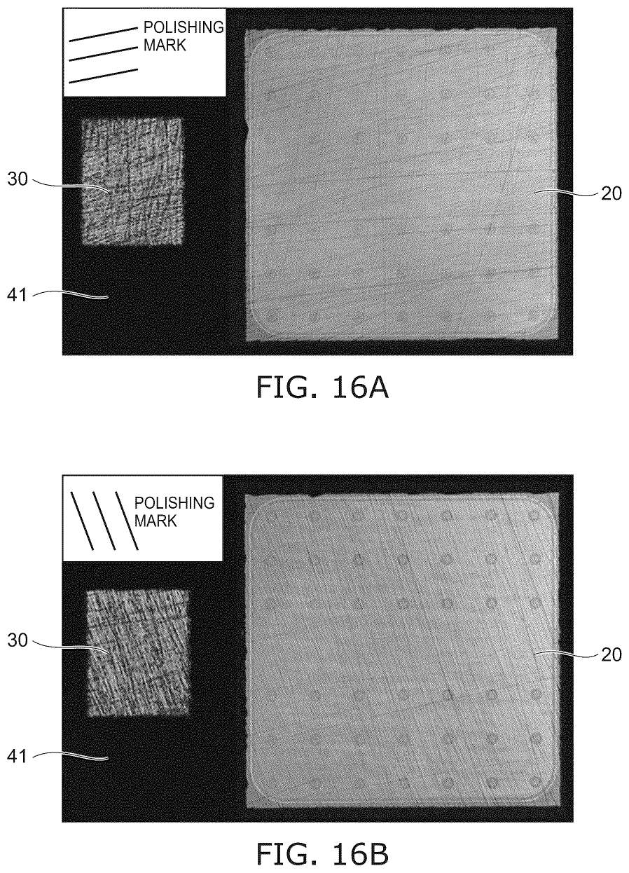

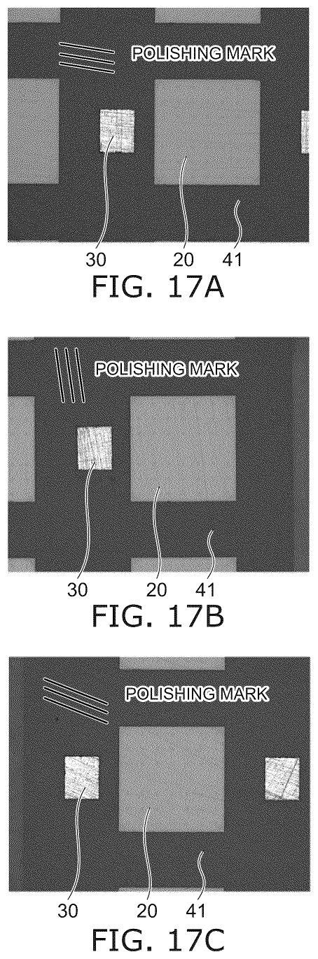

FIG. 16A, FIG. 16B, and FIGS. 17A to 17C are micrographs showing the appearances after polishing the light-emitting element, the protection element, and the first covering member.

FIGS. 16A and 16B were imaged using a surface roughness measuring device VK-3100 made by Keyence Corporation in a state in which laser light used for the roughness measurement was irradiated.

FIGS. 17A to 17C were imaged using a digital microscope VHX-8000 made by Keyence Corporation in a state in which light was irradiated by coaxial lighting in which the optical axis of the camera lens was substantially the same as the optical axis of the illumination light.

FIG. 16A, FIG. 16B, and FIGS. 17A to 17C are imaging results of mutually-different samples. In FIG. 16A, FIG. 16B, and FIGS. 17A to 17C, three line segments illustrate the direction of polishing marks resulting from the polishing.

As shown in FIG. 16A, FIG. 16B, and FIGS. 17A to 17C, polishing marks that extend in the same direction were formed in the upper surface 20a of the light-emitting element 20 and the upper surface 30a of the protection element 30.

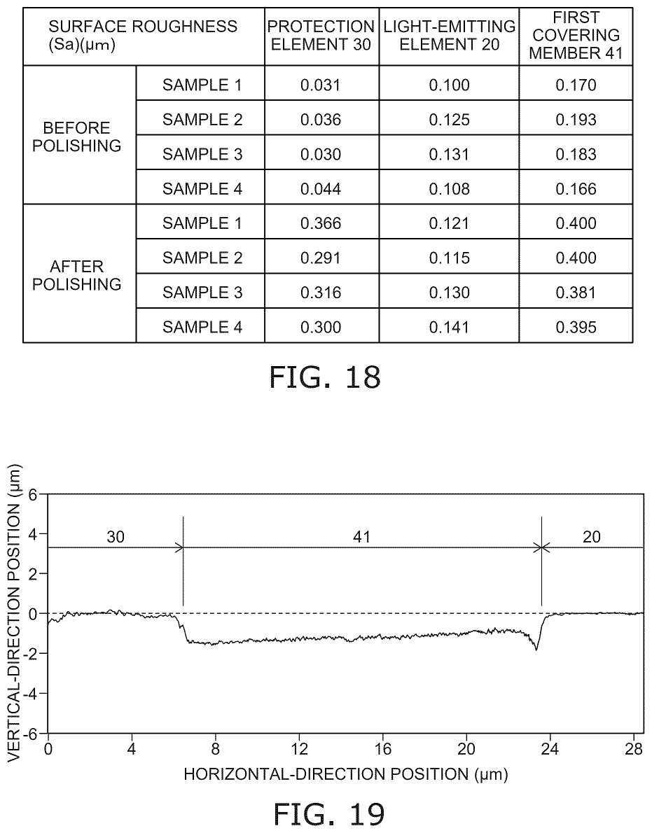

FIG. 18 is a table showing measurement results of the surface roughnesses of the light-emitting element, the protection element, and the first covering member.

As shown in FIG. 18, the surface roughness (Sa) before and after polishing was measured by laser light irradiation using the surface roughness measuring device VK-3100 made by Keyence Corporation for the four samples. As a result, in the samples after polishing, the surface roughness (Sa) of the upper surface 30a of the protection element 30 was greater and rougher than the surface roughness (Sa) of the upper surface 20a of the light-emitting element 20. The surface roughness (Sa) of the upper surface 41a of the first covering member 41 was greater and rougher than the surface roughness (Sa) of the upper surface 30a of the protection element 30.

The sapphire of the upper surface 20a of the light-emitting element 20 was harder than the silicon of the upper surface 30a of the protection element 30; and the silicon was harder than the silicone resin of the upper surface 41a of the first covering member 41. Therefore, by performing the polishing by using a grindstone of a grit that can polish sapphire, which was hardest, it is estimated that the surface roughness (Sa) could be higher for the materials having lower hardnesses.

FIG. 19 is a graph showing the surface profile of one sample. The horizontal axis is the horizontal-direction position; and the vertical axis is the vertical-direction position.

The surface profile was measured by laser light irradiation using the surface roughness measuring device VK-3100 made by Keyence Corporation for the one sample after polishing.

As shown in FIG. 19, the upper surface 30a of the protection element 30 and the upper surface 20a of the light-emitting element 20 were positioned in substantially the same plane. On the other hand, the upper surface 41a of the first covering member 41 was positioned about 1 μm lower than the upper surface 30a of the protection element 30 and the upper surface 20a of the light-emitting element 20. It is considered that this is because the first covering member 41 was softer than the protection element 30 and the light-emitting element 20 and easier to polish.

The embodiments above are examples embodying the invention; and the invention is not limited to these embodiments. For example, additions, deletions, or modifications of some of the components or processes according to the embodiments above also are included in the invention.

The invention can be utilized as, for example, a light source of a lighting device, etc.

What is claimed is:

1. A method for manufacturing a light-emitting device, the method comprising:
providing a structure body, the structure body including
a wiring substrate including a wiring part at an upper surface,
a light-emitting element in which a pair of first electrodes, a first semiconductor layer, and a first element substrate are stacked, and
a protection element in which a pair of second electrodes, a second semiconductor layer, and a second element substrate are stacked,
wherein the pair of first electrodes and the pair of second electrodes face the upper surface of the wiring substrate, and the pair of first electrodes and the pair of second electrodes are connected to the wiring part; and
removing at least a portion of the first element substrate of the light-emitting element and at least a portion of the second element substrate of the protection element from the structure body.

2. The method according to claim 1, further comprising
between the providing of the structure body and the removing of the at least the portion of the first element substrate and the at least the portion of the second element substrate, disposing a first covering member on the wiring substrate, wherein
the first covering member fixes the first electrodes of the light-emitting element, the second electrodes of the protection element, and the wiring substrate.

3. The method according to claim 2, wherein
the disposing of the first covering member includes covering the first element substrate and the second element substrate with the first covering member, and
the removing of the at least the portion of the first element substrate and the at least the portion of the second element substrate includes a first removal process of removing at least the portion of the first element substrate, at least the portion of the second element substrate, and a portion of the first covering member from a side of the structure body opposite to the wiring substrate.

4. The method according to claim 3, wherein
the removing of the at least the portion of the first element substrate and the at least the portion of the second element substrate further includes a second removal process of removing a remaining portion of the first covering member after the first removal process.

5. The method according to claim 1, wherein
the first semiconductor layer includes an n-type semiconductor layer, an active layer, and a p-type semiconductor layer in this order from the first element substrate side, and
the removing of the at least the portion of the first element substrate and the at least the portion of the second element substrate includes removing an entirety of the first element substrate and removing a portion of the n-type semiconductor layer.

6. The method according to claim 1, wherein
the second element substrate is a semiconductor substrate,
the second semiconductor layer includes
a first semiconductor region connected to one of the second electrodes, and
a second semiconductor region spaced apart from the first semiconductor region, the second semiconductor region being connected to the other of the second electrodes, and
the removing of the at least the portion of the first element substrate and the at least the portion of the second element substrate includes removing the portion of the second element substrate while allowing an entirety of the second semiconductor layer to remain.

7. The method according to claim 2, further comprising
after the removing of the at least the portion of the first element substrate and the at least the portion of the second element substrate:
disposing a light-transmitting member on the light-emitting element; and
disposing a second covering member on the first covering member, the second covering member covering a lateral surface of the light-transmitting member, and the second covering member not covering an upper surface of the light-transmitting member.

8. The method according to claim 4, further comprising
after the second removal process:
disposing a light-transmitting member on the light-emitting element; and
disposing a second covering member on the wiring substrate, the second covering member covering a lateral surface of the protection element, a lateral surface of the light-emitting element, and a lateral surface of the light-transmitting member, while not covering an upper surface of the light-transmitting member.

9. The method according to claim 3, wherein
the first removal process includes polishing the structure body from a surface at the side opposite to the wiring substrate.

10. A light-emitting device comprising:
a wiring substrate;
a light-emitting element arranged on the wiring substrate;
a protection element arranged on the wiring substrate;
a light-transmitting member arranged on the light-emitting element; and
a covering member arranged on the wiring substrate, the covering member not covering an upper surface of the light-transmitting member while covering a lateral surface of the light-emitting element and a lateral surface of the protection element, wherein
an upper surface of the light-emitting element and an upper surface of the protection element are positioned in a same plane.

11. The light-emitting device according to claim 10, wherein
the covering member includes
a first covering member covering the lateral surface of the light-emitting element and the lateral surface of the protection element, an upper surface of the first covering member being positioned in the same plane as the upper surface of the light-emitting element and the upper surface of the protection element; and
a second covering member arranged on the first covering member, the second covering member covering the upper surface of the protection element and a lateral surface of the light-transmitting member.

12. The light-emitting device according to claim 11, wherein
the second covering member has a higher reflectance than the first covering member for light emitted from the light-emitting element.

13. The light-emitting device according to claim 10, wherein
a thickness of the light-emitting element is not less than 20 μm and not more than 80 μm.

14. The light-emitting device according to claim 10, wherein
a surface roughness of the upper surface of the protection element is greater than a surface roughness of the upper surface of the light-emitting element.

15. The light-emitting device according to claim 10, wherein
a surface roughness of the upper surface of the first covering member is greater than a surface roughness of the upper surface of the light-emitting element and a surface roughness of the upper surface of the protection element.
